(19) United States
(12) Patent Application Publication
(10) Pub. No.: US 2011/0234337 A1
(43) Pub. Date: Sep. 29, 2011

(54) Filter circuit for differential communication

(75) Inventors: Takashi Saitou, Okazaki-shi (JP); Akira Takaoka, Okazaki-shi (JP); Hideki Saito, Anjo-shi (JP); Nobuya Watabe, Nagoya (JP); Tomohiro Kuno, Nagoya (JP)

(73) Assignees: Nippon Soken, Inc., Nishio-city (JP); DENSO CORPORATION, Kariya-city (JP)

(21) Appl. No.: 13/065,546

(22) Filed: Mar. 24, 2011

(30) Foreign Application Priority Data
Mar. 26, 2010 (JP) 2010-072517
Mar. 2, 2011 (JP) 2011-045536

(51) Int. Cl. H03H 7/00

(52) U.S. Cl. 333/175

(57) ABSTRACT

In a filter circuit, first and second coils are connected to first and second communication lines, respectively. At a secondary side of the first and second coils, first and second capacitors are connected in series between the first and second communication lines. At a primary side of the first and second coils, third and fourth capacitors are connected in series between the first and second communication lines. A connection node between the first and second capacitors is grounded. A connection node between the third and fourth capacitors is grounded. The first and second coils are adjacently arranged in order to have a reversed polarity to each other. The filter circuit having the above structure works as a n-type filter capable of eliminate both common mode noise and normal mode noise. The filter circuit can eliminate noise caused by the first and second coils.

### CROSS-REFERENCE TO RELATED APPLICATION

This application is related to and claims priority from Japanese Patent Applications No. 2010-072517 filed on Mar. 26, 2010 and No. 2011-045536 filed on Mar. 2, 2011, the contents of which are hereby incorporated by reference.

### BACKGROUND OF THE INVENTION

1. Field of the Invention

The present invention relates to filter circuits used for differential communication, capable of eliminating common mode noise which is harmful electrical interference with reference to the common or ground wire.

2. Description of the Related Art

There are conventional filter circuits capable of eliminating common mode noise generated in signal transmission lines for differential communication. For example, conventional patent documents such as Japanese latent laid open publication No. JP 2007-318734 and Japanese patent No. 3195588 have disclosed such conventional techniques.

In the conventional technique disclosed in the former Japanese patent laid open publication No. JP 2007-318734, one or more capacitors are placed in series between a first communication line and a second communication line, and the capacitors are grounded through one or more resistances.

In the conventional technique disclosed in the latter Japanese patent, a common mode choke coil is connected between the first communication line and the second communication line.

Further, there are other conventional filter circuits for eliminating normal mode noise generated in differential communication lines. In such conventional filter circuits, a capacitor is placed between a first communication line and a second communication line. Further, coils, etc. are placed on the first communication line and the second communication line, respectively.

However, the conventional filter circuits having the above structures disclosed in Japanese latent laid open publication No. JP 2007-318734 and Japanese patent No. 3195588 have a complicated circuit configuration because they require many components such as the capacitors, resistances, etc. which are placed in these communication lines.

Still further, when one or more components is eliminated from communication lines for differential communication in order to avoid the total number of components connected to the communication lines from increasing, this causes a drawback of deteriorating the noise reduction capability of the filter circuit. In this case, the filter circuit cannot effectively eliminate common mode noise and normal mode noise from the communication lines.

### SUMMARY OF THE INVENTION

It is an object of the present invention to provide a filter circuit which is used for a differential communication capable of efficiently eliminating both common node noise and normal mode noise which are the target to be eliminated from communication lines of the differential communication.

To achieve the above purpose, the present invention provides a filter circuit which is placed between a first communication line and a second communication line. The first communication line and the second communication line are used for differential communication. The filter circuit has a first coil, a second coil, a first capacitor and a second capacitor. The first coil is placed at the first communication line side. The second coil is placed at the second communication line side. The first capacitor and the second capacitor are placed at one of a primary side and a secondary side of the first coil and the second coil. The first capacitor and the second capacitor are further placed in series between the first communication line and the second communication line. In the filter circuit according to the present invention, a connection node between the first capacitor and the second capacitor is grounded.

The characteristics of the first coil, the second coil, the first capacitor and the second capacitor are selected so that a filter constant in the first communication line and a filter constant in the second communication line becomes the same value when observed from the connection node between the first capacitor and the second capacitor. The first coil and the second coil are adjacently placed in order to eliminate emission noise radiated by magnetic flux generated in the first and second coils when receiving common mode noise.

This structure of the filter circuit according to the present invention makes it possible to eliminate common mode noise of not less than a resonance frequency of the first coil and the first capacitor from the first communication line, and further eliminate common mode noise of not less than a resonance frequency of the second coil and the second capacitor from the second communication line with high efficiency.

Further, the above structure of the filter circuit according to the present invention makes it possible to eliminate normal mode noise of not less than a resonance frequency of an equivalent circuit comprised of the first coil, the second coil, the first capacitor and the second capacitor with high efficiency.

The filter circuit according to the present invention can effectively eliminate both common mode noise and normal mode noise.

Because the configuration of the filter circuit according to the present invention does not require any additional component such as a capacitor and a coil, it is possible for the filter circuit composed of a minimum number of components to eliminate both common mode noise and normal mode nose.

In the configuration of the filter circuit according to the present invention, the primary side of each of the first coil and the second coil indicates the input side which receives noise, and the secondary side indicates the output side which is opposite to the primary side.

By the way, the filter circuit according to the present invention has two coils such as the first coil and the second coil. When the first coil and the second coil are arranged regardless of the position thereof, magnetic flux generated in one of the coils is input to the other coil. This often generates noise.

In order to eliminate such radiated emission noise caused by the magnetic flux generated in the first coil and the second coil, the present invention provides the structure of the filter circuit in which the first coil and the second coil are adjacently arranged in order to cancel the magnetic flux generated in the first coil and the second coil to each other.

This arrangement of the first coil and the second coil makes it possible to cancel the magnetic flux generated in them to each other. It is therefore possible for the filter circuit according to the present invention to effectively eliminate noise caused by the magnetic flux generated in and radiated from the first coil and the second coil even if the first coil and the second coil receive common mode noise.

As described above, the filter circuit according to the present invention can eliminate both common mode noise and normal mode noise by using a simple configuration composed of at least the first coil, the second coil, the first capacitor and the second capacitor.

Still further, the filter circuit according to the present invention can efficiently eliminate noises generated by magnetic fluxes radiated from each of the coils because the coils are adjacently arranged to each other so as to cancel the generated magnetic flux together.

Further, it is also possible for the filter circuit according to the present invention to have a suitable resistance in order to ground the first capacitor and the second capacitor through the resistance.

The filter circuit as another aspect of the present invention further has a third capacitor and a fourth capacitor connected in series between the first communication line and the second communication line. The third capacitor and the fourth capacitor are placed at one of the primary side and the secondary side of the first and second coils which is the side opposite to the side at which the first capacitor and the second capacitor are placed.

In the filter circuit, a connection node between the third capacitor and the fourth capacitor is grounded, and the characteristics of the first coil, the second coil, the first capacitor, the second capacitor, the third capacitor and the fourth capacitor are selected so that a filter constant in the first communication line and a filter constant in the second communication line become the same value when observed from the connection node between the first capacitor and the second capacitor.

Because this structure of the filter circuit according to the present invention makes a π-type filter to both common mode noise and normal mode noise, it is possible to efficiently eliminate both common mode noise and normal mode noise.

When the normal mode noise is forwardly eliminated as compared with the common mode noise, it is possible for the filter circuit to further have an across-the-line capacitor placed between the first communication line and the second communication line, and placed at one of the primary side and the secondary side of the first and second coils which is the side opposite to the side where the first capacitor and the second capacitor are placed.

Further, it is preferable to apply the filter circuit according to the present invention to a device mounted on a motor vehicle which is grounded. In particular, the filter circuit according to the present invention can efficiently eliminate or cancel both normal mode noise and common mode noise generated on communication lines which connect an on-vehicle antenna with a drive circuit.

### BRIEF DESCRIPTION OF THE DRAWINGS

A preferred, non-limiting embodiment of the present invention will be described by way of example with reference to the accompanying drawings, in which:

FIG. 1 is a view showing a schematic configuration of a vehicle antenna device of a vehicle equipped with a filter circuit according to an embodiment of the present invention;

FIG. 2 is a view showing a configuration of the filter circuit according to the embodiment of the present invention;

FIG. 3A is a view showing an equivalent circuit of the filter circuit according to the embodiment capable of eliminating common mode noise;

FIG. 3B is a view showing an equivalent circuit of the filter circuit according to the embodiment capable of eliminating normal mode noise;

FIG. 4A is a graph showing a relationship between a frequency (kHz) and a noise voltage (dBV) of the output of the filter circuit according to the embodiment shown in FIG. 2 as a result after the filter circuit eliminates common mode noise;

FIG. 4B is a graph showing a relationship between a frequency (kHz) and a noise voltage (dBV) of the output of the filter circuit according to the embodiment shown in FIG. 2 as a result after the filter circuit eliminates normal mode noise;

FIG. 4C is a view showing a configuration of a filter circuit as a comparison circuit;

FIG. 5A is a view showing the strength (or intensity) of radiated emission noise output from coils in a filter circuit in which the coils are adjacently arranged so that the polarity of each of the coils has the same direction;

FIG. 5B is a view showing a strength (or intensity) of radiated emission noise output from the coils in the filter circuit according to the embodiment of the present invention in which the coils are adjacently arranged so that the polarity of each of the coils has a different direction; and

FIG. 6 is a view showing another circuit configuration of the filter circuit according to the embodiment of the present invention.

### DETAILED DESCRIPTION OF THE PREFERRED EMBODIMENTS

Hereinafter, various embodiments of the present invention will be described with reference to the accompanying drawings. In the following description of the various embodiments, like reference characters or numerals designate like or equivalent component parts throughout the several diagrams.

### Embodiment

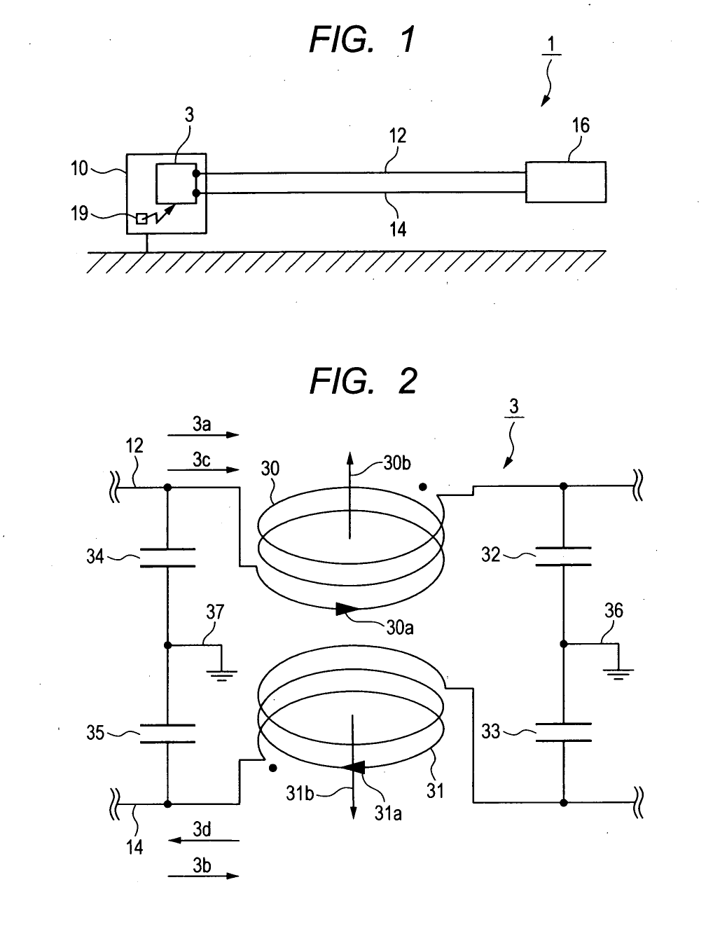

A description will be given of the filter circuit according to the embodiment of the present invention with reference to FIG. 1 to FIG. 6.

FIG. 1 is a view showing a schematic configuration of a vehicle antenna system in which the filter circuit according to the embodiment is placed. As shown in FIG. 1, the filter circuit 3 according to the embodiment is mounted to an antenna device 1 of a vehicle. The antenna device 1 is used for performing a differential communication.

The antennal device 1 is comprised of a drive circuit 10, a pair of first and second communication lines 12 and 14, and an antenna part 16. The drive circuit 10 is grounded to a vehicle body. A pair of the first communication line 12 and the second communication line 14 is extended from the drive circuit 10. The antenna part 16 is placed at a front end part of the first and second communication lines 12 and 14.

As shown in FIG. 1, the drive circuit 10 is placed in a primary side when observed from the first and second communication lines 12 and 14. On the other hand, the antenna part 16 is placed in a secondary side when observed from the first and second communication lines 12 and 14.

Next, a description will now be given of the filter circuit 3 according to the embodiment.

The filter circuit 3 is incorporated in the drive circuit 10 and eliminates normal mode noise 3c and 3d and common mode noise 3a and 3b. The normal mode noise and common mode noise are generated in the noise generation source 19 in the drive circuit 10 and becomes mixed with communication signals transferred in the first and second communication lines 12 and 14.

FIG. 2 is a view showing a configuration of the filter circuit 3 according to the embodiment of the present invention.

As shown in FIG. 2, the filter circuit 3 is comprised of two coils 30 and 31 and four capacitors 32 to 35. The coil (first coil) 30 is connected to the first communication line 12. The coil (second coil) 31 is connected to the second communication line 14. These coils 30 and 31 are placed in parallel and reversely placed on the same surface of a substrate of the drive circuit 10 in order to cancel magnetic fluxes generated in the coils 30 and 31. The magnetic fluxes are generated in the coils 30 and 31 and discharged to the outside when the coils 30 and 31 receive the common mode noise.

The capacitors (first and second capacitors) 32 and 33 are connected in series between the first communication line 12 and the second communication line 14 placed at the secondary side of the coils 30 and 31.

On the other hand, the capacitors (third and fourth capacitors) 34 and 35 are connected in series between the first communication line 12 and the second communication line 14 placed at the primary side of the coils 30 and 31.

A connection node between the capacitors 32 and 33 is connected to a ground line 36 of a vehicle. On the other hand, a connection node between the capacitors 34 and 35 is connected to a ground line 37 of the vehicle.

The two coils 30 and 31 and the four capacitors 32 to 35 are selected so that they have equal characteristics and symmetry and the filter circuit 3 has a filter constant which satisfies the following equation when receiving higher harmonic frequency noise such as normal mode noise and common mode noise having a frequency f [Hz]:

f=1/2π√(L30×C32)=1/2π√(L30×C34)=1/2π√(L31×C31)=1/2 π√(L31×C33).

Specifically, the filter circuit 3 is comprised of the capacitors 32 to 35 having 0.22 μF of capacitance, and the coils 30 and 31 having 4.7 μH of inductance in order to have a filter cutting frequency of 155 kHz, maintain the differential communication frequency of 125 kHz, and decrease higher harmonic noise.

In the configuration of the filter circuit 3 which is comprised of the two coils 30 and 31 and the four capacitors 32 to 35 according to the embodiment, each of the first communication line 12 and the second communication line 14 has the same filter constant when observed from the ground lines 36 and 37.

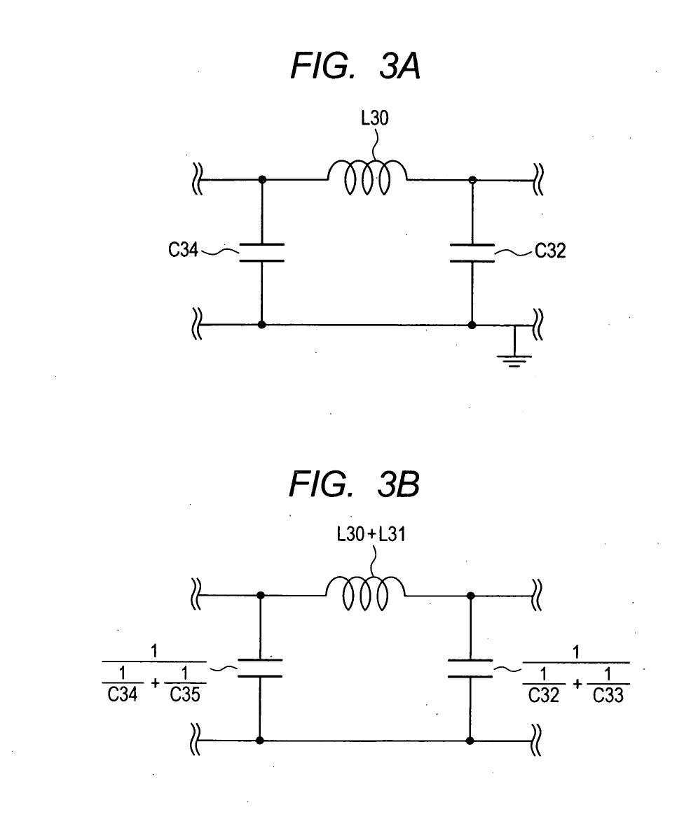

FIG. 3A is a view showing an equivalent circuit of the filter circuit 3 according to the embodiment capable of eliminating common mode noise. FIG. 3B is a view showing an equivalent circuit of the filter circuit 3 according to the embodiment capable of eliminating normal mode noise.

In FIG. 3A and FIG. 3B, reference characters L30, L31, C32, C33, C34 and C35 designate filter constants of the coils 30, 31 and the capacitors 32, 33, 34 and 35, respectively. That is, reference character L30 indicates the inductance of the coil 30, and L31 denotes the inductance of the coil 31, C32 designates the capacitance of the capacitor 32, C33 indicates the capacitance of the capacitor 33, C34 indicates the capacitance of the capacitor 34, and C35 indicates the capacitance of the capacitor 35.

The equivalent circuit of the filter circuit 3 has the circuit between the ground and the first communication line 12 or the second communication line 14 shown in FIG. 3A in the views to explain the common mode noise 3a and 3b.

In particular, the equivalent circuit of the filter circuit 3 is a π-type filter comprised of the inductance L30, the capacitance C32 and the capacitance C34 in the view of the first communication line.

Further, the equivalent circuit of the filter circuit 3 becomes a π-type filter comprised of the inductances L30+L31, the capacitance of 1/(1/C32+1/C32), and 1/(1/C34+1/C35) in the view of the normal mode noise 3c and 3d as shown in FIG. 3B.

Next, a description will now be given of the noise reduction of the normal mode noise 3c, 3d and the common node noise 3a, 3b by the filter circuit 3 having the above configuration according to the embodiment.

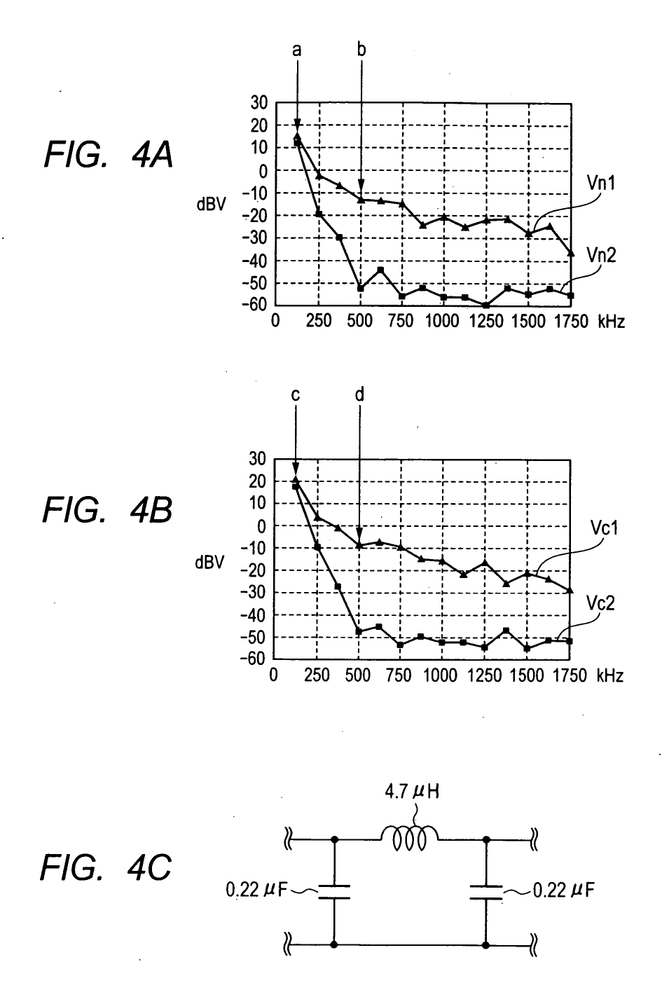

FIG. 4A is a graph showing a relationship between a frequency (kHz) and a noise voltage (dBV) of the output of the filter circuit 3 according to the embodiment shown in FIG. 2 as a result after the filter circuit 3 eliminates common mode noise. FIG. 4B is a graph showing a relationship between a frequency (kHz) and a noise voltage (dBV) of the output of the filter circuit 3 according to the embodiment shown in FIG. 2 as a result after the filter circuit 3 eliminates normal mode noise.

FIG. 4C is a view showing a configuration of a filter circuit as a comparison circuit. As shown in FIG. 4C, the comparison circuit is comprised of the coil having 4.7 μH of inductance and two capacitors having 0.22 μF of the same capacitance. The coil is connected in series to the first communication line. The capacitors are placed at the primary side of the coil and the secondary side of the coil, respectively.

In FIG. 4A, the horizontal axis shows a frequency (kHz). The vertical axis shows a normal mode noise voltage Vn1 of the comparison filter circuit shown in FIG. 4C, and also shows a normal mode noise voltage Vn1 of the filter circuit 3 according to the embodiment. These normal mode noise voltages Vn1 and Vn2 become a higher harmonic frequency component of a differential communication signal at the output and input terminals of the filter circuit.

It can be understood from the result shown in FIG. 4A, the filter circuit 3 according to the embodiment drastically decreases the higher harmonic frequency component while maintaining the level of the differential communication signal (approximately 3 dB decreasing, as designated by the arrow “a”), when compared with the result of the comparison filter circuit.

On the other hand, as shown in FIG. 4B, the horizontal axis shows a frequency (kHz). The vertical axis shows a common mode noise voltage Vc1 of the comparison filter circuit shown in FIG. 4C, and also shows a common mode noise voltage Vc2 of the filter circuit 3 according to the embodiment. These common mode noise voltages Vc1 and Vc2 become a higher harmonic frequency component of a differential communication signal at the output and input terminals of the filter circuit.

It can be understood from the result shown in FIG. 4B, the filter circuit 3 according to the embodiment drastically decreases the higher harmonic frequency component while maintaining the level of the differential communication signal (approximately 2 dB decreasing, as designated by the arrow “c”), when compared with the result of the comparison filter circuit.

Next, a description will now be given of the effect of decreasing noise by the arrangement of the coils 30 and 31 in the filter circuit 3 according to the embodiment of the present invention.

The filter circuit 3 of the embodiment is equipped with the coil 30 and the coil 31. In the configuration of this filter circuit 3, there is a possibility of reflecting magnetic flux generated by the coils 30 and 31, and the generated magnetic flux is radiated and transmitted as radiated emission noise on the first communication line 12 and the second communication line 14.

The radiated emission noise is generated when a common mode current flows through the coil 30 and the coil 31.

In order to avoid the radiated emission noise, the filter circuit 3 according to the embodiment has the configuration in which the coils 30 and 31 are arranged on the substrate of the drive circuit 10 so that the polarity of the coil 30 is reversed to the polarity of the coil 31.

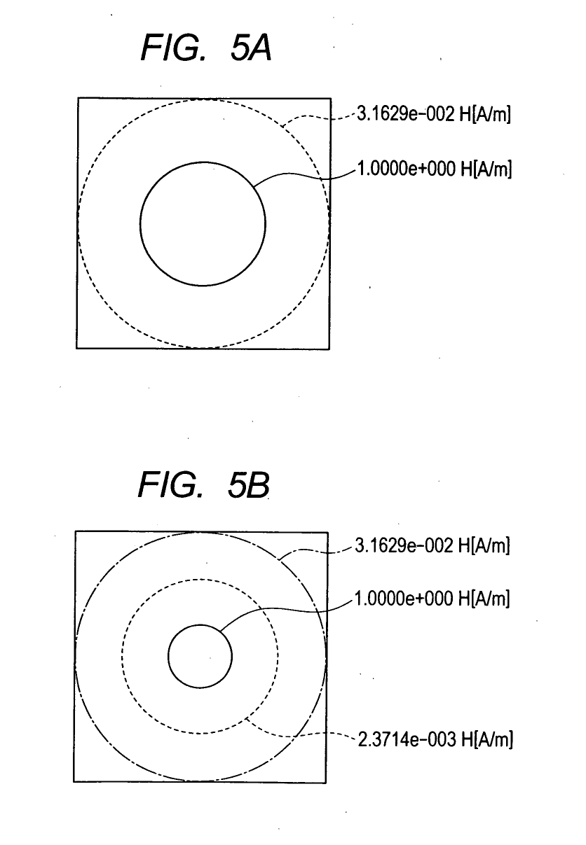

FIG. 5A is a view showing the strength (or intensity) of radiated emission noise output from the coils 30 and 31 in the filter circuit 3 in which the coils 30 and 31 are adjacently arranged on the drive circuit 10 so that the polarity of each of the coils 30 and 31 has the same direction.

On the other hand, FIG. 5B is a view showing a strength (or intensity) of radiated emission noise output from the coils 30 and 31 in the filter circuit 3 according to the embodiment of the present invention in which the coils 30 and 31 are adjacently arranged on the substrate of the drive circuit 10 so that the polarity of each of the coils has a different direction.

As can be understood from FIG. 5A and FIG. 5B, the structure of the coils 30 and 31 having the reversed polarity direction to each other shown in FIG. 5B can more decrease the emission noise radiated from the coils 30 and 31 than the structure if the case shown in FIG. 5A in which the coils are arranged to have the same polarity direction.

The filter circuit 3 having the above structure according to the embodiment of the present invention can decrease the radiated emission noise by approximately 15 dB.

The antennal device 1 equipped with the filter circuit 3 according to the embodiment of the present invention has the following effects. Because the filter circuit 3 according to the embodiment of the present invention forms a π-type filter structure for both normal mode noise 3c, 3d and common mode noise 3a, 3b, the filter circuit 3 can eliminate such emission noise radiated from the coils with high efficiency as shown in FIG. 4A and FIG. 4B.

As shown in FIG. 4A, the filter circuit 3 according to the embodiment of the present invention can efficiently eliminate noise of not less than a harmonic frequency generated by a combination of the coil 30 and the capacitor 32 or the capacitor 34, or a combination of the coil 31 and the capacitor 33 or the capacitor 35 in the common mode noise 3a and 3b overlapped on the first communication line 12 and the second communication line 14.

Further, as shown in FIG. 4B, the filter circuit 3 according to the embodiment of the present invention can efficiently eliminate normal mode noise 3c and 3d of not less than a harmonic frequency expressed by the equivalent circuit of the coils 30, 31 and the capacitors 32 to 35.

Accordingly, it is possible for the filter circuit 3 according to the embodiment of the present invention to efficiently eliminate both the common mode noise 3a and 3b and the normal mode noises 3c and 3d.

By the way, when these coils 30 and 31 are arranged without considering any positional relationship between them, because the filter circuit has the coils 30 and 31, there is a possibility of affecting the magnetic flux generated in one of the coils 30 or 31 generated into the other coil 30 or 31 when receiving the common mode noise.

In order to avoid this, the filter circuit 3 according to the embodiment of the present invention has the configuration in which the coils 30 and 31 are arranged while considering the positional relationship thereof so that the magnetic flux generated in the coil 30 and the magnetic flux generated in the coil 31 when receiving the common mode noise are canceled to each other. This makes it possible for the filter circuit 3 to efficiently eliminate the noise generated by the magnetic flux emitted from the coils 30 and 31 because the magnetic flux generated in the coil 30 and the magnetic flux generated in the coil 31 are cancelled to each other even if the coils 30 and 31 receive the common mode noise.

Because the filter circuit 3 according to the embodiment of the present invention has the structure in which the coils 30 and 31 are arranged in order to have a reversed polarity to each other, it is possible to efficiently decrease radiated emission noise generated by the magnetic flux generated by the coils 30 and 31.

### (Relationship Between the Components of the Filter Circuit 3 According to the Embodiment and the Claims)

The coils 30 and 31 correspond to a first coil and a second coil, respectively which are used in the claims.

The capacitor 32 corresponds to a second capacitor, the capacitors 34 and 35 correspond to a third capacitor and a fourth capacitor, respectively which are used in the claims.

### (Another Modification)

The filter circuit 3 according to the embodiment of the present invention has the structure in which the capacitor is electrically connected to the first communication line 12 and the second communication line 14 so that the capacitors are approximately arranged in a line symmetry in the primary side and the secondary side of the coils 30 and 31. The concept of the present invention is not limited by this structure.

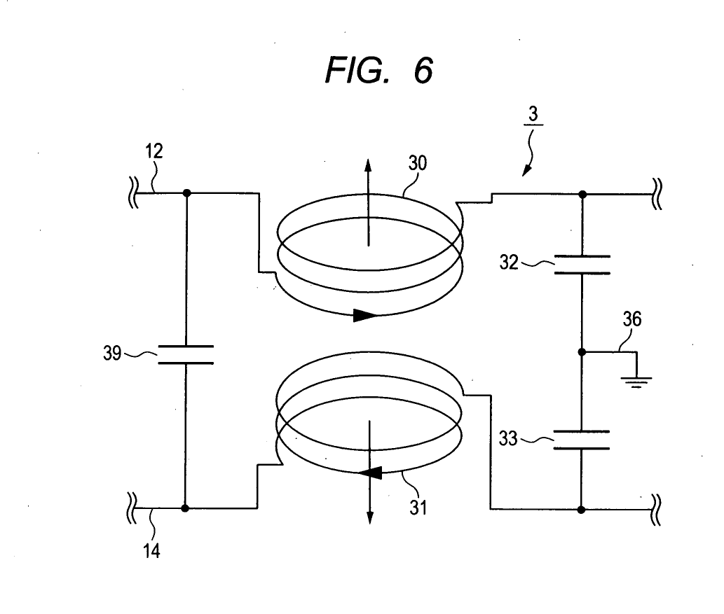

FIG. 6 is a view showing another circuit configuration of the filter circuit 3 according to the embodiment of the present invention. As shown in FIG. 6, when the secondary side of the coils 30 and 31 has the capacitors 32 and 33 only, it is possible to replace the capacitors 34 and 35 placed at the primary side of the coils 30 and 31 with an across-the-line capacitor 39 in order to eliminate normal mode noise 3c, 3d when the secondary side has the coils 32 and 33 only.

In the structure of the filter circuit 3 according to the embodiment, the coils 32 to 35 are grounded. The present invention is not limited by the structure. It is possible to ground these coils 32 to 35 through resistances.

While specific embodiments of the present invention have been described in detail, it will be appreciated by those skilled in the art that various modifications and alternatives to those details could be developed in light of the overall teachings of the disclosure. Accordingly, the particular arrangements disclosed are meant to be illustrative only and not limited to the scope of the present invention which is to be given the full breadth of the following claims and all equivalents thereof.

What is claimed is:

1. A filter circuit placed between a first communication line and a second communication line in a differential communication, comprising:
a first coil placed at the first communication line side;
a second coil placed at the second communication line side; and
a first capacitor and a second capacitor placed at one of a primary side and a secondary side of the first coil and the second coil, and further placed in series between the first communication line and the second communication line,
wherein a connection node between the first capacitor and the second capacitor is grounded, and the characteristics of the first coil, the second coil, the first capacitor and the second capacitor are selected so that a filter constant in the first communication line and a filter constant in the second communication line are the same value when observed from the connection node between the first capacitor and the second capacitor, and
the first coil and the second coil are adjacently placed in order to eliminate emission noise radiated by magnetic flux generated in the first and second coils when receiving common mode noise.

2. The filter circuit according to claim 1, further comprising:
a third capacitor and a fourth capacitor connected in series between the first communication line and the second communication line, and placed at one of the primary side and the secondary side of the first and second coils which is the side opposite to the side at which the first capacitor and the second capacitor are placed,
wherein a connection node between the third capacitor and the fourth capacitor is grounded, and the characteristics of the first coil, the second coil, the first capacitor, the second capacitor, the third capacitor and the fourth capacitor are selected so that a filter constant in the first communication line and a filter constant in the second communication line have the same value when observed from the connection node between the first capacitor and the second capacitor.

3. The filter circuit according to claim 1, further comprising an across-the-line capacitor placed between the first communication line and the second communication line, and placed at one of the primary side and the secondary side of the first and second coils which is the side opposite to the side at which the first capacitor and the second capacitor are placed,

4. The filter circuit according to claim 1, wherein the filter circuit is used in an antenna device mounted on a vehicle, and the connection node between the first capacitor and the second capacitor is grounded to the vehicle.

5. The filter circuit according to claim 2, wherein the filter circuit is used in an antenna device mounted on a vehicle, and the connection node between the third capacitor and the fourth capacitor is grounded to the vehicle.

6. The filter circuit according to claim 3, wherein the filter circuit is used in an antenna device mounted on a vehicle, and the across-the-line capacitor is grounded to the vehicle.

7. The filter circuit according to claim 1, wherein the first communication line and the second communication line are antenna lines of an antenna device equipped with the filter circuit mounted on a vehicle.
